(19) United States
(12) Patent Application Publication
(10) Pub. No.: US 2025/0240013 A1
(43) Pub. Date: Jul. 24, 2025

(54) MOTOR DRIVER IMPROVING RESONANCE NOISE CAUSED BY MOTOR

(71) Applicant: ANPEC ELECTRONICS CORPORATION, HSINCHU (TW)

(72) Inventors: KUN-MIN CHEN, HSINCHU CITY (TW); YI-CHENG LIU, NEW TAIPEI CITY (TW); YEN-PING WANG, HSINCHU (TW)

(21) Appl. No.: 18/657,941

(22) Filed: May 8, 2024

(30) Foreign Application Priority Data
Jan. 19, 2024 (TW) 113102184

(51) Int. Cl. H03K 17/16; H02P 7/03; H02P 7/29

(52) U.S. Cl. CPC H03K 17/162; H02P 7/04; H02P 7/29; H03K 2217/0063; H03K 2217/0072

(57) ABSTRACT

A motor driver improving resonance noise caused by a motor is provided. The motor driver sets one or more duty cycle threshold ranges. When a duty cycle of each waveform of a duty cycle input signal does not fall within the one or more duty cycle threshold ranges, the motor driver directly drives the motor according to the duty cycle input signal. When the duty cycle of any waveforms of the duty cycle input signal falls within the one or more duty cycle threshold ranges, the motor driver adjusts the duty cycles of some waveforms of the duty cycle input signal within specified time such that the duty cycles of at least two of the plurality of waveforms of the duty cycle input signal are different from each other, and drives the motor according to the adjusted duty cycle input signal.

### CROSS-REFERENCE TO RELATED PATENT APPLICATION

This application claims the benefit of priority to Taiwan Patent Application No. 113102184, filed on Jan. 19, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to motor drivers, and more particularly to a motor driver improving resonance noise caused by a motor.

### BACKGROUND OF THE DISCLOSURE

Fans are widely used in electronic equipment to cool processors and other heating components. When the fan vibrates and runs at a certain speed, it will resonate with other components inside the casing of the electronic equipment, thus generating noise. In this case, more time is needed in manually adjusting the fan mechanism and detecting the noise spectrum.

### SUMMARY OF THE DISCLOSURE

In response to the above-referenced technical inadequacies, the present disclosure provides a motor driver improving resonance noise caused by a motor, including: a duty cycle determination circuit and a motor driver circuit. The duty cycle determination circuit is configured to set a lower limit duty cycle and an upper limit duty cycle of a duty cycle threshold range and determine that when a duty cycle of each of a plurality of waveforms of a duty cycle input signal falls within the duty cycle threshold range, the motor driver adjusts the duty cycle of each of the plurality of waveforms of the duty cycle input signal generated within a specified time to make duty cycles of at least two of the plurality of waveforms of the duty cycle input signal different from each other, and outputs a duty cycle output signal according to an adjusted duty cycle input signal. The motor driver circuit is connected to the duty cycle determination circuit and a motor and configured to output a motor drive signal to the motor according to the duty cycle output signal received from the duty cycle determination circuit to drive the motor.

As mentioned above, the present disclosure provides a motor driver improving resonance noise caused by a motor. When the motor driver of the present disclosure drives the motor of the fan, the driving mode used can cause slight disturbance in the rotation speed of the motor of the fan, so that the resonance energy is not concentrated, and the amplitude of the resonance energy is reduced, thereby reducing the amplitude of resonance energy and the noise.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a block diagram of a motor driver improving resonance noise caused by a motor according to a first embodiment of the present disclosure;

FIG. 2 is a block diagram of a motor driver improving resonance noise caused by a motor according to a second embodiment of the present disclosure;

FIG. 3 is a block diagram of a motor driver improving resonance noise caused by a motor according to a third embodiment of the present disclosure;

FIG. 4 is a circuit diagram of an output stage circuit and a driver circuit of the motor driver improving resonance noise caused by a motor according to the first to third embodiments of the present disclosure when applied to a single-phase motor;

FIG. 5 is a circuit diagram of an output stage circuit and a driver circuit of the motor driver improving resonance noise caused by a motor according to the first to third embodiments of the present disclosure when applied to a three-phase motor;

FIG. 6 is a schematic diagram of a duty cycle threshold range set by the motor driver improving resonance noise caused by a motor according to the first to third embodiments of the present disclosure;

FIG. 7 is a schematic diagram of a duty cycle of the duty cycle input signal adjusted by the motor driver improving resonance noise caused by a motor according to the first to third embodiments of the present disclosure; and

FIG. 8 is a schematic diagram of a rotation speed of a motor driven by the motor driver improving resonance noise caused by a motor according to the first to third embodiments of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether or not a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

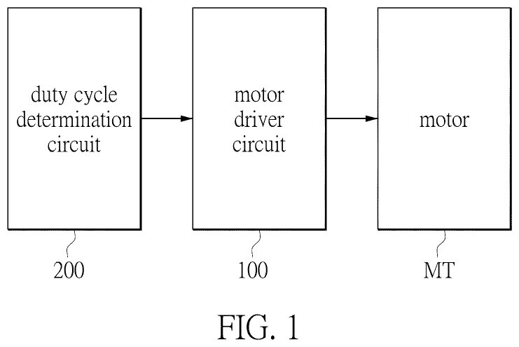

Reference is made to FIG. 1, which is a block diagram of a motor driver improving resonance noise caused by a motor according to a first embodiment of the present disclosure.

The motor driver according to the first embodiment of the present disclosure includes a motor driver circuit 100 and a duty cycle determination circuit 200, which are used to drive a motor MT (such as but not limited to a fan motor), while improving the resonance noise generated by the motor MT and other circuit components.

The motor driver circuit 100 is connected to the duty cycle determination circuit 200 and the motor MT.

The rotation speed of the motor MT depends on the duty cycle of a duty cycle output signal used for the drive control of the motor MT. When the motor MT maintains running at a certain speed, it will resonate with other circuit components and generate noise.

Therefore, the duty cycle determination circuit 200 of the motor driver of the present disclosure sets a lower limit duty cycle and an upper limit duty cycle of a duty cycle threshold range. The duty cycle determination circuit 200 determines whether or not the duty cycle of each of a plurality of waveforms of a duty cycle input signal falls within a duty cycle threshold range (that is, whether or not it is equal to any one of a plurality of duty cycle thresholds within a duty cycle threshold range) to determine whether or not to adjust the duty cycle input signal to output the duty cycle output signal.

When the duty cycle of each of the plurality of waveforms of the duty cycle input signal does not fall into the duty cycle threshold range, the duty cycle determination circuit 200 does not adjust the duty cycle of each of the plurality of waveforms of the duty cycle input signal. For example, a target duty cycle corresponding to a target rotation speed of the motor is maintained. Then, the duty cycle determination circuit 200 directly outputs the duty cycle output signal to the motor driver circuit 100 according to an unadjusted duty cycle input signal.

On the contrary, when the duty cycle of any one of the plurality of waveforms of the duty cycle input signal falls into the duty cycle threshold range, the duty cycle determination circuit 200 adjusts the duty cycle of each of the plurality of waveforms of the duty cycle input signal generated within a specified time period to make the duty cycle of at least two of the plurality of waveforms of the duty cycle input signal different from each other, such as adjusting the duty cycles of two, three or more of the plurality of waveforms of the duty cycle input signal to be different values. Then, the duty cycle determination circuit 200 outputs the duty cycle output signal to the motor driver circuit 100 according to the adjusted duty cycle input signal.

The motor driver circuit 100 outputs a motor drive signal to the motor MT according to the duty cycle output signal received from the duty cycle determination circuit 200, thereby driving the motor MT. The rotation speed of the motor MT depends on the duty cycle of the duty cycle output signal.

If the duty cycle determination circuit 200 adjusts the duty cycle of all or a part of the plurality of waveforms of the duty cycle input signal to output the duty cycle output signal and the motor driver circuit 100 drives the motor MT of a fan according to the duty cycle output signal, the rotation speed of the motor MT changes with the change of the duty cycle output signal to cause a slight disturbance in the rotation speed of the motor MT, so as to reduce the energy of resonance with other circuit components when the motor MT maintains operation at a certain speed, thereby reducing the resonance sound.

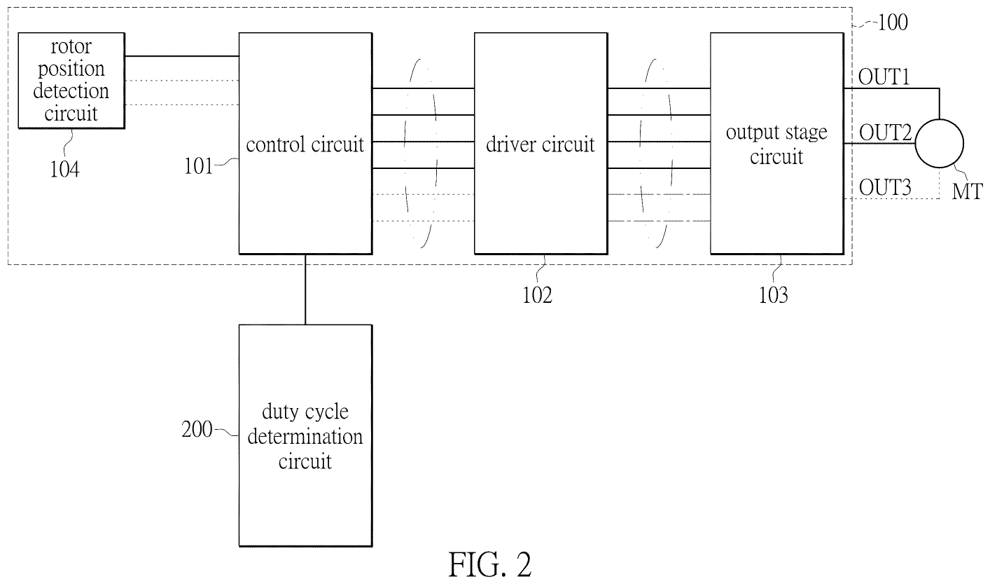

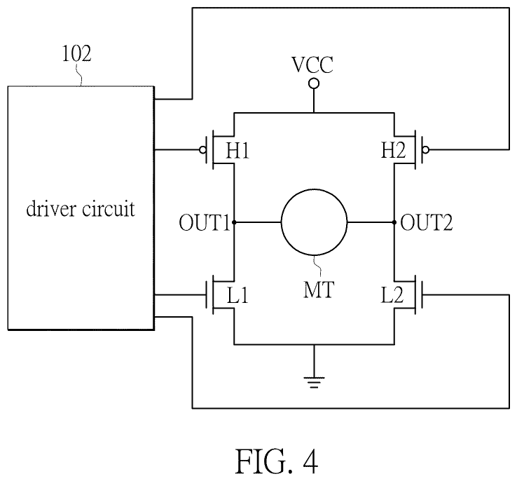

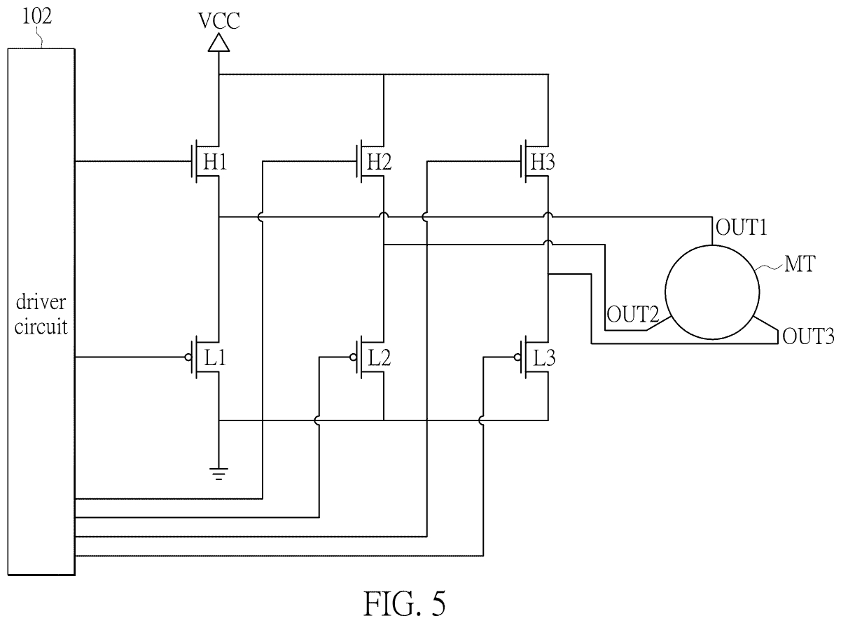

Reference is made to FIGS. 2, 4 and 5. FIG. 2 is a block diagram of a motor driver improving resonance noise caused by a motor according to a second embodiment of the present disclosure, FIG. 4 is a circuit diagram of an output stage circuit and a driver circuit of the motor driver improving resonance noise caused by a motor according to the first to third embodiments of the present disclosure when applied to a single-phase motor, and FIG. 5 is a circuit diagram of an output stage circuit and a driver circuit of the motor driver improving resonance noise caused by a motor according to the first to third embodiments of the present disclosure when applied to a three-phase motor.

The motor MT driven by the motor driver of the present disclosure can be a single-phase motor as shown in FIG. 4 or a three-phase motor as shown in FIG. 5.

The similarities between the second embodiment of the present disclosure and the first embodiment of the present disclosure will not be described again here.

In the second embodiment, the motor driver circuit 100 of the motor driver of the present disclosure may include a control circuit 101, a driver circuit 102, an output stage circuit 103 and a rotor position detection circuit 104.

The rotor position detection circuit 104 can be provided in the motor MT and connected to an input end of the control circuit 101. The output end of the control circuit 101 is connected to an input end of the driver circuit 102. An output end of the driver circuit 102 is connected to an input end of the output stage circuit 103. An output end of the output stage circuit 103 is connected to the motor MT.

The rotor position detection circuit 104 may be, for example, but not limited to, a Hall sensor used to detect the position of the rotor of the motor MT to output a rotor position detection signal.

The control circuit 101 outputs one or more control signals according to the duty cycle output signal received from the duty cycle determination circuit 200 and the rotor position detection signal received from the rotor position detection circuit 104. The driver circuit 102 outputs one or more drive signals according to the one or more control signals received from the control circuit 101. The output stage circuit 103 operates according to the one or more drive signals received from the driver circuit 102 to output one or more motor drive signals to the motor MT.

If the motor MT driven by the motor driver of the present disclosure is a single-phase motor, the output stage circuit 103 as shown in FIG. 4 may include a first high-side switch H1, a first low-side switch L1, a second high-side switch H2, and a second low-side switch L2.

A first end of the first high-side switch H1 is coupled to a common voltage VCC. A first end of the first low-side switch L1 is connected to a second end of the first high-side switch H1. A second end of the first low-side switch L1 is grounded. A node between the first end of the first low-side switch L1 and the second end of the first high-side switch H1 is connected to a first end OUT1 of the motor MT.

A first end of the second high-side switch H2 is coupled to the common voltage VCC. A first end of the second low-side switch L2 is connected to a second end of the second high-side switch H2. A second end of the second low-side switch L2 is grounded. A node between the first end of the second low-side switch L2 and the second end of the second high-side switch H2 is connected to a second end OUT2 of the motor MT.

A control end of the first high-side switch H1, a control end of the first low-side switch L1, a control end of the second high-side switch H2 and a control end of the second low-side switch L2 are connected to an output end of the driver circuit 102.

The driver circuit 102 outputs a plurality of drive signals to the control end of the first high-side switch H1, the control end of the first low-side switch L1, the control end of the second high-side switch H2 and the control end of the second low-side switch L2 respectively according to the plurality of control signals received from the control circuit 101.

If the motor MT driven by the motor driver of the present disclosure is a three-phase motor, the output stage circuit 103 as shown in FIG. 5, in addition to the first high-side switch H1, the first low-side switch L1, the second high-side switch H2 and the second low-side switch L2, may further include a third high-side switch H3 and a third low-side switch L3.

A first end of the third high-side switch H3 is coupled to the common voltage VCC. A first end of the third low-side switch L3 is connected to a second end of the third high-side switch H3. A second end of the third low-side switch L3 is grounded. A node between the first end of the third low-side switch L3 and the second end of the third high-side switch H3 is connected to a third end OUT3 of the motor MT.

The first end OUT1 of the motor MT, the second end OUT2 of the motor MT, and the third end OUT3 of the motor MT can be respectively the U-phase end of the three-phase motor, the V-phase end of the three-phase motor, and the W-phase end of the three-phase motor.

The control end of the first high-side switch H1, the control end of the first low-side switch L1, the control end of the second high-side switch H2, the control end of the second low-side switch L2, the control end of the third high-side switch H3 and the control end of the third low-side switch L3 are connected to the output end of the driver circuit 102.

The driver circuit 102 outputs a plurality of drive signals to the control end of the first high-side switch H1, the control end of the first low-side switch L1, the control end of the second high-side switch H2, the control end of the second low-side switch L2, the control end of the third high-side switch H3 and the control end of the third low-side switch L3 respectively according to the plurality of control signals received from the control circuit 101.

It should be understood that the first high-side switch H1, the first low-side switch L1, the second high-side switch H2, the second low-side switch L2, the third high-side switch H3 and the third low-side switch L3 can all be transistors, and the shape of the switches can be adjusted according to actual needs, and the present disclosure is not limited thereto.

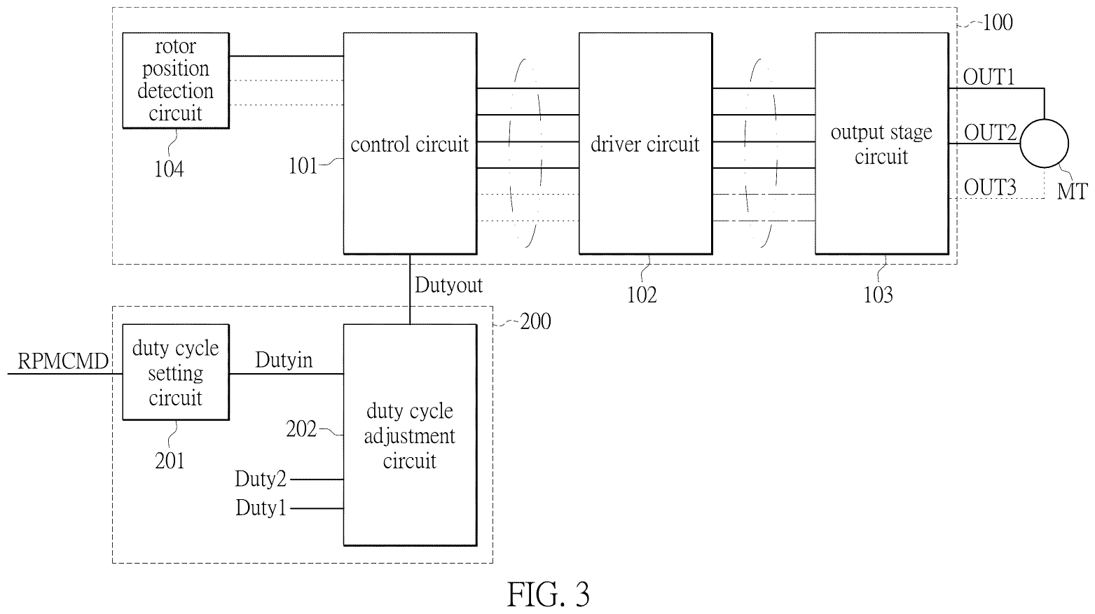

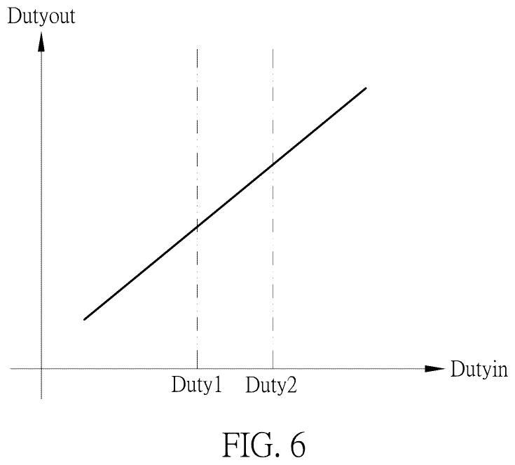

Reference is made to FIGS. 3 and 6. FIG. 3 is a block diagram of a motor driver improving resonance noise caused by a motor according to a third embodiment of the present disclosure, and FIG. 6 is a schematic diagram of a duty cycle threshold range set by the motor driver improving resonance noise caused by a motor according to the first to third embodiments of the present disclosure.

The similarities between the third embodiment of the present disclosure and the second embodiment of the present disclosure will not be described again here.

In the third embodiment, the duty cycle determination circuit 200 of the motor driver of the present disclosure includes a duty cycle setting circuit 201 and a duty cycle adjustment circuit 202. The duty cycle adjustment circuit 202 is connected to the duty cycle setting circuit 201 and the control circuit 101.

The duty cycle setting circuit 201 of the duty cycle determination circuit 200 can set duty cycles of the plurality of waveforms of a duty cycle input signal Dutyin according to a target rotation speed of the motor MT indicated by a motor rotation speed command signal RPMCMD received from an external speed indication circuit.

The duty cycle adjustment circuit 202 of the duty cycle determination circuit 200 sets a lower limit duty cycle Duty1 and an upper limit duty cycle Duty2 of a duty cycle threshold range. The duty cycle adjustment circuit 202 determines whether or not the duty cycle of each of the plurality of waveforms of the duty cycle input signal Dutyin received from the duty cycle setting circuit 201 falls within the duty cycle threshold range to determine whether or not to adjust the duty cycle of each of the plurality of waveforms of the duty cycle input signal Dutyin.

When the duty cycle of all or a part of the waveforms of the duty cycle input signal Dutyin received by the duty cycle adjustment circuit 202 from the duty cycle setting circuit 201 falls within the duty cycle threshold range, the duty cycle determination circuit 200 adjusts the duty cycle of one or more of the plurality of waveforms of the duty cycle input signal Dutyin, and outputs a duty cycle output signal Dutyout according to the adjusted duty cycle input signal Dutyin.

Alternatively, in practice, the duty cycle adjustment circuit 202 of the duty cycle determination circuit 200 may set an upper limit duty cycle and a lower limit duty cycle for a plurality of duty cycle threshold intervals. When the duty cycle adjustment circuit 202 determines that the duty cycle of any one of plurality of waveforms of the duty cycle input signal Dutyin received from the duty cycle setting circuit 201 falls within any one of the plurality of duty cycle threshold intervals, the duty cycle adjustment circuit 202 of the duty cycle determination circuit 200 adjusts the duty cycle of one or more of the plurality of waveforms of the duty cycle input signal and outputs the duty cycle output signal Dutyout according to the adjusted duty cycle input signal.

The control circuit 101 controls the driver circuit 102 to drive the output stage circuit 103 according to the duty cycle output signal Dutyout received from the duty cycle adjustment circuit 202.

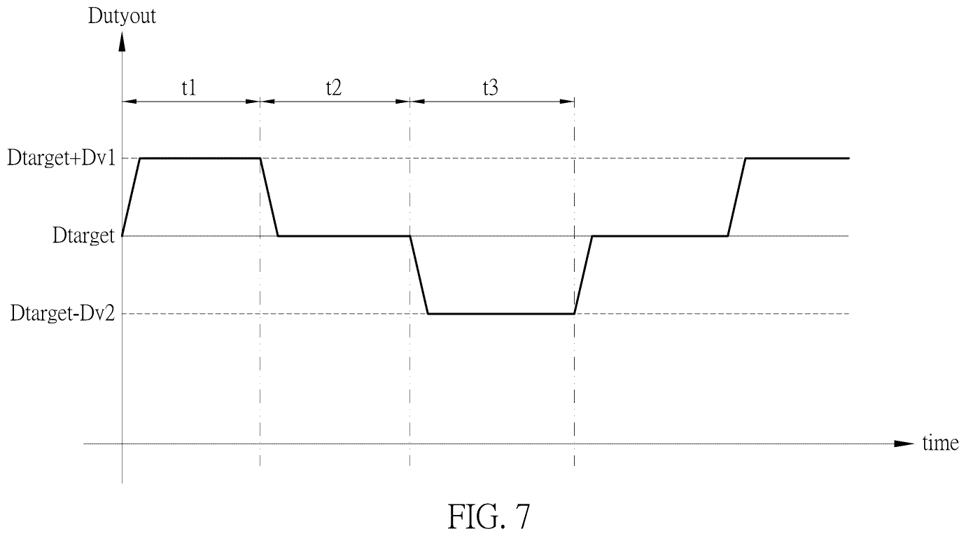

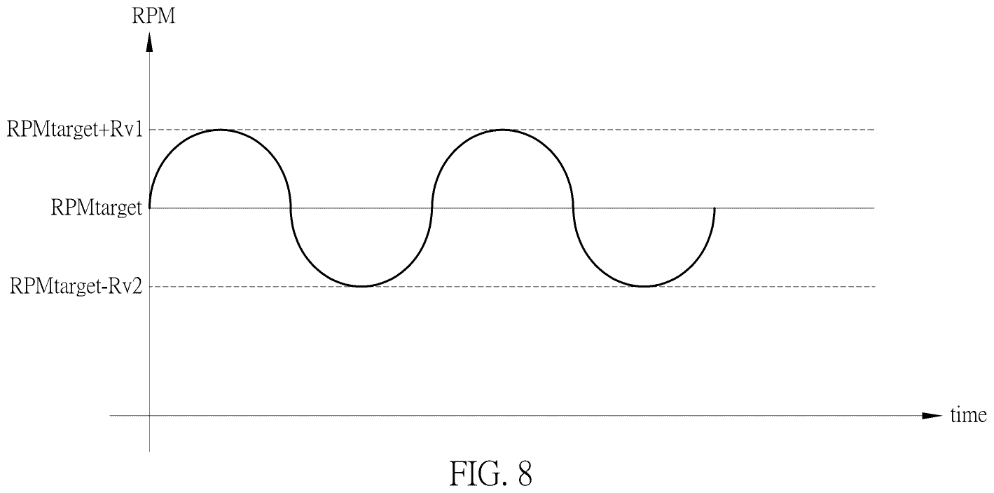

Reference is made to FIG. 7 and FIG. 8. FIG. 7 is a schematic diagram of a duty cycle of the duty cycle input signal adjusted by the motor driver improving resonance noise caused by a motor according to the first to third embodiments of the present disclosure, and FIG. 8 is a schematic diagram of a rotation speed of a motor driven by the motor driver improving resonance noise caused by a motor according to the first to third embodiments of the present disclosure.

The duty cycle determination circuit 200 as shown in FIG. 1 or FIG. 2 or the duty cycle adjustment circuit 202 of the duty cycle determination circuit 200 as shown in FIG. 3 can set a target duty cycle corresponding to a target rotation speed of the motor MT, and can set a target duty cycle decrease ratio, a target duty cycle increase ratio, or both.

When the duty cycle of any one of the plurality of waveforms of the duty cycle input signal (such as the duty cycle input signal Dutyin as shown in FIG. 3) falls into any one of the plurality of duty cycle threshold intervals, the duty cycle determination circuit 200 or the duty cycle adjustment circuit 202 of the duty cycle determination circuit 200 as shown in FIG. 3 can adjust the target duty cycle decrease ratio of the duty cycle of one or more of the plurality of waveforms of the duty cycle input signal Dutyin received from the duty cycle setting circuit 201, and/or adjusts the target duty cycle increase ratio of the duty cycle of one or more of the plurality of waveforms of the duty cycle input signal Dutyin.

For example, the duty cycle determination circuit 200 as shown in FIG. 1 or FIG. 2 or the duty cycle adjustment circuit 202 of the duty cycle determination circuit 200 as shown in FIG. 3 can have a configuration shown in FIG. 7; in the duty cycle input signal, the duty cycle of one or more of the plurality of waveforms generated in a time interval t1 is increased from a target duty cycle Dtarget by a target duty cycle increase ratio Dv1, the duty cycle of one or more of the plurality of waveforms generated in another time interval t2 is reduced from a target duty cycle Dtarget by a target duty cycle decrease ratio Dv2, and the duty cycle of one or more of the plurality of waveforms generated in yet another time interval t3 is maintained at a target duty cycle Dtarget.

Alternatively, in practice, the duty cycle determination circuit 200 as shown in FIG. 1 or FIG. 2 or the duty cycle adjustment circuit 202 of the duty cycle determination circuit 200 as shown in FIG. 3 can set a plurality of duty cycle threshold intervals respectively corresponding to a plurality of target duty cycle decrease ratios and a plurality of target duty cycle increase ratios.

The duty cycle determination circuit 200 or the duty cycle adjustment circuit 202 of the duty cycle determination circuit 200 as shown in FIG. 3 can determine that each of the plurality of waveforms of the duty cycle input signal falls which one of the plurality of duty cycle threshold intervals to determine which one or more of the plurality of target duty cycle decrease ratios and the plurality of target duty cycle increase ratios is used to adjust one or more of the plurality of waveforms of the duty cycle input signal.

That is to say, the duty cycle of the duty cycle input signal adjusted by the duty cycle determination circuit 200 or the duty cycle adjustment circuit 202 of the duty cycle determination circuit 200 as shown in FIG. 3 is not a constant value; that is, instead of maintaining the target duty cycle Dtarget corresponding to the target rotation speed of the motor MT, the duty cycle of the duty cycle input signal slightly changes up and down over time according to the target duty cycle Dtarget.

The duty cycle determination circuit 200 as shown in FIG. 1 or FIG. 2 or the duty cycle adjustment circuit 202 of the duty cycle determination circuit 200 as shown in FIG. 3 outputs the duty cycle output signal Dutyout to the control circuit 101 of the motor driver circuit 100 according to the adjusted duty cycle input signal.

When the motor driver circuit 100 drives the motor MT according to the duty cycle output signal Dutyout as shown in FIG. 7, the rotation speed of the motor MT, as shown in FIG. 8, gradually increases from a target rotation speed RPMtarget to the target rotation speed increase ratio Rv1 in a time interval, and gradually decreases from a target rotation speed RPMtarget to a target rotation speed decrease ratio Rv2 in another time interval. That is, the rotation speed of the motor MT produces a slight disturbance so that the resonance energy is not concentrated and the amplitude of the resonance energy is reduced, thereby reducing the noise.

The target duty cycle increase ratio described in the present specification is less than a duty cycle adjustment ratio threshold, and the target duty cycle decrease ratio is smaller than a duty cycle adjustment ratio threshold to avoid excessive rapid instantaneous changes in rotation speed.

In summary, the present disclosure provides a motor driver improving resonance noise caused by a motor. When the motor driver of the present disclosure drives the motor of the fan, the driving mode used can cause slight disturbance in the rotation speed of the motor of the fan, so that the resonance energy is not concentrated, and the amplitude of the resonance energy is reduced, thereby reducing the amplitude of resonance energy and the noise.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A motor driver improving resonance noise caused by a motor, including:
a duty cycle determination circuit configured to set a lower limit duty cycle and an upper limit duty cycle of a duty cycle threshold range, and determine that when a duty cycle of each of a plurality of waveforms of a duty cycle input signal falls within the duty cycle threshold range, the motor driver adjusts the duty cycle of each of the plurality of waveforms of the duty cycle input signal generated within a specified time to make duty cycles of at least two of the plurality of waveforms of the duty cycle input signal different from each other, and outputs a duty cycle output signal according to an adjusted duty cycle input signal; and
a motor driver circuit connected to the duty cycle determination circuit and a motor, and configured to output a motor drive signal to the motor according to the duty cycle output signal received from the duty cycle determination circuit to drive the motor.

2. The motor driver according to claim 1, wherein the motor driver circuit includes:
a control circuit, connected to the duty cycle determination circuit and configured to output a control signal according to the duty cycle output signal received from the duty cycle determination circuit;
a driver circuit, connected to the control circuit and configured to output a drive signal according to the control signal received from the control circuit; and
an output stage circuit, connected to the driver circuit and the motor and configured to operate according to the drive signal received from the driver circuit to output the motor drive signal to the motor.

3. The motor driver according to claim 2, wherein the motor driver circuit further includes:
a rotor position detection circuit provided on the motor, connected to the control circuit and configured to detect a position of a rotor of the motor to output a rotor position detection signal, wherein the control circuit control circuit outputs the control signal according to the rotor position detection signal and the duty cycle output signal received from the rotor position detection circuit.

4. The motor driver according to claim 2, wherein the output stage circuit includes:
a first high-side switch, wherein a first end of the first high-side switch is coupled to a common voltage;
a first low-side switch, wherein a first end of the first low-side switch is connected to a second end of the first high-side switch, a second end of the first low-side switch is grounded, and a node between the first end of the first low-side switch and the second end of the first high-side switch is connected to a first end of the motor;
a second high-side switch, wherein a first end of the second high-side switch is coupled to the common voltage; and
a second low-side switch, wherein a first end of the second low-side switch is connected to a second end of the second high-side switch, a second end of the second low-side switch is grounded, a node between the first end of the second low-side switch and the second end of the second high-side switch is connected to a second end of the motor;
wherein a control end of the first high-side switch, a control end of the first low-side switch, a control end of the second high-side switch and a control end of the second low-side switch are connected to the driver circuit.

5. The motor driver according to claim 4, wherein the output stage circuit further includes:
a third high-side switch, wherein a first end of the third high-side switch is coupled to the common voltage; and
a third low-side switch, wherein a first end of the third low-side switch is connected to a second end of the third high-side switch, a second end of the third low-side switch is grounded, and a node between the first end of the third low-side switch and the second end of the third high-side switch is connected to a third end of the motor;
wherein a control end of the third high-side switch and a control end of the third low-side switch are connected to the driver circuit.

6. The motor driver according to claim 1, wherein the duty cycle determination circuit receives a motor rotation speed command signal from an externally-connected rotation speed indicating circuit, determines the duty cycle of each of the plurality of waveforms of the duty cycle input signal according to a target rotation speed of the motor indicated by the motor rotation speed command signal, and generates the duty cycle input signal.

7. The motor driver according to claim 1, wherein, when the duty cycle of each of the plurality of waveforms of the duty cycle input signal does not fall within the duty cycle threshold range, the duty cycle determination circuit directly outputs the duty cycle output signal to the motor driver circuit according to an unadjusted duty cycle input signal.

8. The motor driver according to claim 1, wherein, when the duty cycle of each of the plurality of waveforms of the duty cycle input signal does not fall within the duty cycle threshold range, the duty cycle determination circuit maintains the duty cycle of each of the plurality of waveforms of the duty cycle input signal as a target duty cycle corresponding to the target rotation speed of the motor, and outputs the duty cycle output signal having the plurality of waveforms with duty cycles equal to the target duty cycle to the motor driver circuit.

9. The motor driver according to claim 1, wherein, when the duty cycle of any one of the plurality of waveforms of the duty cycle input signal falls within the duty cycle threshold range, the duty cycle determination circuit adjusts the duty cycle of all or a part of the plurality of waveforms of the duty cycle input signal, and outputs the duty cycle output signal to the motor driver circuit according to the adjusted duty cycle input signal.

10. The motor driver according to claim 1, wherein the duty cycle determination circuit includes:
a duty cycle setting circuit, configured to set duty cycles of the plurality of waveforms of the duty cycle input signal according to the target rotation speed indicated by the motor rotation speed command signal; and
a duty cycle adjustment circuit, connected to the duty cycle setting circuit and the motor driver circuit and configured to set the lower limit duty cycle and the upper limit duty cycle of the duty cycle threshold range, and determine whether or not the duty cycle of each of the plurality of waveforms of the duty cycle input signal received from the duty cycle setting circuit falls within the duty cycle threshold range to determine whether or not to adjust the duty cycle input signal to output the duty cycle output signal to the motor driver circuit.

11. The motor driver according to claim 1, wherein the duty cycle determination circuit sets a lower limit duty cycle and an upper limit duty cycle of each of a plurality of duty cycle threshold intervals, and the duty cycle threshold range includes a plurality of duty cycle threshold intervals; and
when the duty cycle of any one of the plurality of waveforms of the duty cycle input signal falls into any one of the plurality of duty cycle threshold intervals, the duty cycle determination circuit adjusts the duty cycle of one or more of the plurality of waveforms of the duty cycle input signal, and outputs the duty cycle output signal according to the adjusted duty cycle input signal.

12. The motor driver according to claim 1, wherein the duty cycle determination circuit sets a target duty cycle increase ratio; and
when the duty cycle of any one of the plurality of waveforms of the duty cycle input signal falls into any one of the plurality of duty cycle threshold intervals, the duty cycle determination circuit increases the target duty cycle increase ratio of the duty cycle of one or more of the plurality of waveforms of the duty cycle input signal and outputs the duty cycle output signal according to the adjusted duty cycle input signal.

13. The motor driver according to claim 1, wherein the duty cycle determination circuit sets a target duty cycle decrease ratio; and
when duty cycles of the plurality of waveforms of the duty cycle input signal fall into any one of the plurality of duty cycle threshold intervals, the duty cycle determination circuit reduces the target duty cycle decrease ratio of the duty cycle of one or more of the plurality of waveforms of the duty cycle input signal and outputs the duty cycle output signal according to the adjusted duty cycle input signal.

14. The motor driver according to claim 1, wherein the duty cycle determination circuit sets a target duty cycle corresponding to a target rotation speed of the motor, and sets a target duty cycle increase ratio and a target duty cycle decrease ratio; and
when the duty cycle of any one of the plurality of waveforms of the duty cycle input signal falls into any one of the plurality of duty cycle threshold intervals, the duty cycle determination circuit increases the target duty cycle increase ratio of a duty cycle of a waveform generated within a time interval from the target duty cycle, decreases the target duty cycle decrease ratio of a duty cycle of a waveform generated in another time interval from the target duty cycle, and maintains a duty cycle of a waveform generated in yet another time interval in the duty cycle input signal.

15. The motor driver according to claim 14, wherein the target duty cycle increase ratio is smaller than a duty cycle adjustment ratio threshold.

16. The motor driver according to claim 14, wherein the target duty cycle decrease ratio is smaller than a duty cycle adjustment ratio threshold.
